(19) United States
(12) Patent Application Publication
(10) Pub. No.: US 2004/0161536 A1
(43) Pub. Date: Aug. 19, 2004

(54) Method for depositing a low-k material having a controlled thickness range

(75) Inventors: Chi-I Lang, Sunnyvale, CA (US); Seon-Mee Cho, San Jose, CA (US); Peter Wai-Man Lee, San Jose, CA (US)

Correspondence Address: Patent Counsel, Applied Materials, Inc., P.O. Box 450A, Santa Clara, CA, 95052, US

(73) Assignee: Applied Materials, Inc.

(21) Appl. No.: 10/366,727

(22) Filed: Feb. 14, 2003

(51) Int. Cl. C23C 16/00

(52) U.S. Cl. 427/255.28

(57) ABSTRACT

A method for depositing, with controlled thickness and thickness non-uniformity, a layer of a low-k dielectric material using a chemical vapor deposition process (CVD), which deposits the material for a duration of time during part of the deposition at a higher pressure of reactant gas than during the remaining time of the deposition.

### BACKGROUND OF THE INVENTION

1. Field of the Invention

The present invention generally relates to semiconductor substrate processing systems. More specifically, the present invention relates to a method for depositing materials having low dielectric constant in a semiconductor substrate processing system.

2. Description of the Related Art

In the semiconductor industry, much effort is spent in developing smaller integrated circuit (IC) devices with ever-increasing operating speed. One of the main factors affecting the operating speed of the IC device is the dielectric constant of an inter-metal dielectric (IMD) layer. To satisfy requirements for high integration and high speed, a dual damascene technique is used during fabrication of the IC devices. Further, IMD layers are formed from materials having a dielectric constant less than 4.0, which is the dielectric constant of silicon dioxide (SiO₂). The materials having a dielectric constant less than 4.0 are commonly referred to as low-k materials. The low-k materials comprise carbon-doped dielectrics, such as carbon doped silicon oxide, organic doped silicon glass (OSG), fluorine doped silicon glass (FSG), and the like.

The IC device comprises a plurality of wiring layers formed from metal lines separated from each other and from a substrate (e.g., a silicon (Si) wafer) by IMD layers. The dual damascene technique includes forming one or more insulator layers (e.g., an IMD layer) on the substrate. In an IMD layer, trenches are etched to position metal lines and small contact holes, or via openings, are etched to interconnect the metal lines of adjacent wiring levels. Thereafter, a metal, (e.g., copper (Cu), aluminum (Al), and the like) is deposited upon the substrate. The metal fills the trench and via opening in the IMD layer to form a metal line and a via, respectively.

During fabrication of the advanced IC devices using a dual damascene technique, the thickness and thickness non-uniformity of the IMD layer is highly controlled. Specifically, the thickness of the IMD layer should vary from substrate to substrate less than 5%. Further, the thickness non-uniformity of a layer within the substrate should be less than 2%. Herein the “thickness non-uniformity” is expressed in percent units as a ratio of the difference between the maximal and minimal thickness of the layer to the sum of the maximal thickness and minimal thickness. Films deposited within these thickness limitations do not require planarization.

In the prior art, the deposition process used to form the IMD layer of a low-k material generally requires planarization, such as by chemical-mechanical polishing (CMP). For example, plasma enhanced chemical vapor deposition (CVD) processes produce layers of a low-k material (e.g., carbon doped silicon oxide) having thickness and thickness non-uniformity that may vary within about 6-8% and 3-4%, respectively.

Therefore, there is a need in the art for a method of depositing a low-k dielectric material with highly controlled thickness and thickness non-uniformity during fabrication of an IC device.

### SUMMARY OF THE INVENTION

The present invention is a method for depositing, with controlled thickness and thickness non-uniformity, a layer of a low-k dielectric material, such as carbon doped silicon oxide, organic doped silicon glass (OSG), fluorine doped silicon glass (FSG), and the like. In one embodiment, the method comprises a chemical vapor deposition process (CVD) that deposits the dielectric layer for an initial duration of time at a higher pressure of a reactant gas within a process chamber than during the remaining time of the deposition.

### BRIEF DESCRIPTION OF THE DRAWINGS

The teachings of the present invention can be readily understood by considering the following detailed description in conjunction with the accompanying drawings, in which:

FIG. 1 depicts a schematic diagram of a plasma processing apparatus of the kind used in performing a deposition process in accordance with the present invention;

FIG. 2 depicts a flow diagram of an example of the inventive method of the present invention;

FIGS. 3A-3C depict a sequence of schematic, cross-sectional views of a substrate comprising a low-k dielectric layer being deposited in accordance with the present invention; and

FIG. 4 is a table summarizing the processing parameters of one embodiment of the present invention when practiced using the apparatus of FIG. 1.

To facilitate understanding, identical reference numerals have been used, where possible, to designate identical elements that are common to the figures.

It is to be noted, however, that the appended drawings illustrate only typical embodiments of this invention and are therefore not to be considered limiting of its scope, for the invention may admit to other equally effective embodiments.

### DETAILED DESCRIPTION

The present invention is a method of depositing, with highly controlled thickness repeatability and thickness non-uniformity, a layer of material having a dielectric constant that is less than the dielectric constant of silicon dioxide (SiO₂), which is about 4.0. Herein such materials are referred to as low-k materials. The low-k materials generally comprise carbon-doped dielectrics, such as carbon doped silicon oxide, organic doped silicon glass (OSG), fluorine doped silicon glass (FSG), and the like. Carbon doped silicon oxide processes are available under the trademarks BLACK DIAMOND ™ process or BLACK DIAMOND II™ process from Applied Materials, Inc. of Santa Clara, Calif.

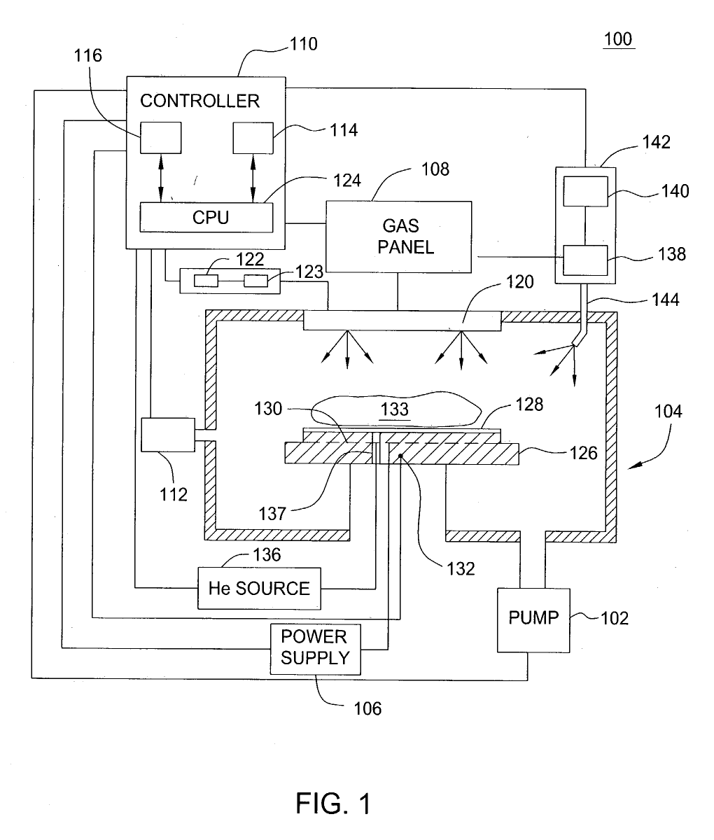

FIG. 1 depicts a schematic diagram of an exemplary chemical vapor deposition (CVD) reactor 100 which may be used to perform a deposition process of the present invention. Herein the reactors performing CVD processes or plasma enhanced CVD processes are collectively referred to as CVD reactors.

An example of a CVD reactor that may used to perform the invention is the Producer® Reactor, available from Applied Materials, Inc. of Santa Clara, Calif. The Producer® Reactor is disclosed in commonly assigned U.S. Pat. No. 5,855,681, issued Jan. 5, 1999, which is incorporated herein by reference. The Producer® Reactor comprises a CVD chamber having two isolated processing regions. Each of the processing regions may be used to deposit the low-k and other materials. FIG. 1 depicts one processing region as a process chamber 104. It should be noted that other CVD reactors and chambers may also be used to practice the invention, e.g., the CVD chamber disclosed in commonly assigned U.S. Pat. No. 6,364,954 B2, issued Apr. 2, 2002, which is incorporated herein by reference. This chamber is available from Applied Materials, Inc. under the trademark DXZ®. Salient features of such CVD reactors and chambers are briefly discussed below.

The reactor 100 comprises a process chamber 104, a gas panel 108, a heater power supply 106, a vacuum pump 102, and a controller 110. Further, the reactor 100 comprises a radio-frequency (RF) source 121 and an optional remote plasma source 142.

The process chamber 104 houses a support pedestal 126, which is used to support a wafer 128 during the CVD deposition process. The support pedestal 126 comprises an embedded heater 130, which is coupled to a controlled heater power supply 106. A temperature sensor 132, such as a thermocouple, is embedded in the support pedestal 126 to monitor, in a conventional manner, the temperature of the pedestal. The measured temperature is used in a feedback loop to regulate the output of the heater power supply 106.

The support pedestal 126 further comprises a gas supply conduit 137, which provides gas, e.g., helium, from a source 136 to the backside of the wafer 128 through grooves (not shown) in the support surface of the pedestal. The gas facilitates heat exchange between the support pedestal 126 and the wafer 128. Using the backside gas, the temperature of the wafer 128 may be controlled between 200 and 800 degrees Celsius.

Process gases 133 are delivered into the process chamber 104 through a showerhead 120. The showerhead 120 is located above the support pedestal 126 and coupled to a gas panel 108, which supplies the process gases into the chamber 104. The showerhead 120 may comprise different zones such that various gases can be released into the process chamber 104 at various flow rates.

A vacuum pump 102 is used to maintain a desired gas pressure in the chamber 104, as well as to evacuate the post-processing gases from the chamber. Gas pressure in the process chamber 104 is monitored by a pressure sensor 112. The measured pressure is used in a feedback loop to control gas pressure in the process chamber 104.

The showerhead 120 and the wafer support pedestal 126 together form a pair of spaced apart electrodes. When RF power is applied to such electrodes, the process gases 133 in the chamber 104 are ignited into a plasma. In one embodiment, the RF source 121, comprising a RF generator 122 and an associated matching network 123, is coupled to the showerhead 120. In one embodiment, the RF source 121 may apply between 500 and 3000 W at about 50 kHz to 13.56 MHz.

Alternatively, the reactant gases may be delivered into the process chamber 104 through the optional remote plasma source 142 comprising a chamber 138, a source 140 of microwave (MW) power, and an outlet tube 144. In this embodiment, a reactant gas is supplied from the gas panel 108 into the chamber 138, where the gas is energized into a plasma using the source 140. The plasma is confined to the chamber 138, while the reactive species from the plasma are directed, through the outlet tube 144, into the process chamber 104. In a further embodiment, a portion of the process gases may be delivered through the showerhead 120, while the remaining gases are delivered, in a form of reactive species, through the remote plasma source 142.

The controller 110 comprises a central processing unit (CPU) 124, a memory 116, and a support circuit 114. The CPU 124 may be of any form of a general purpose computer processor that can be used in an industrial setting. The software routines can be stored in the memory 116, such as random access memory, read only memory, floppy or hard disk drive, or other form of digital storage. The support circuit 114 is conventionally coupled to the CPU 124 and may comprise cache, clock circuits, input/output subsystems, power supplies, and the like.

The software routines, when executed by the CPU 124, transform the CPU into a specific purpose computer (controller) 110 that controls the reactor 100 such that the processes are performed in accordance with the present invention. The software routines may also be stored and/or executed by a second controller (not shown) that is located remotely from the reactor 100.

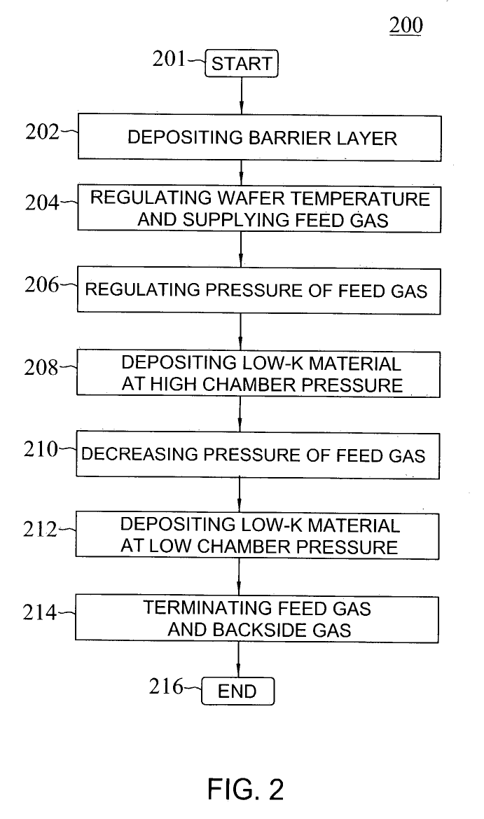

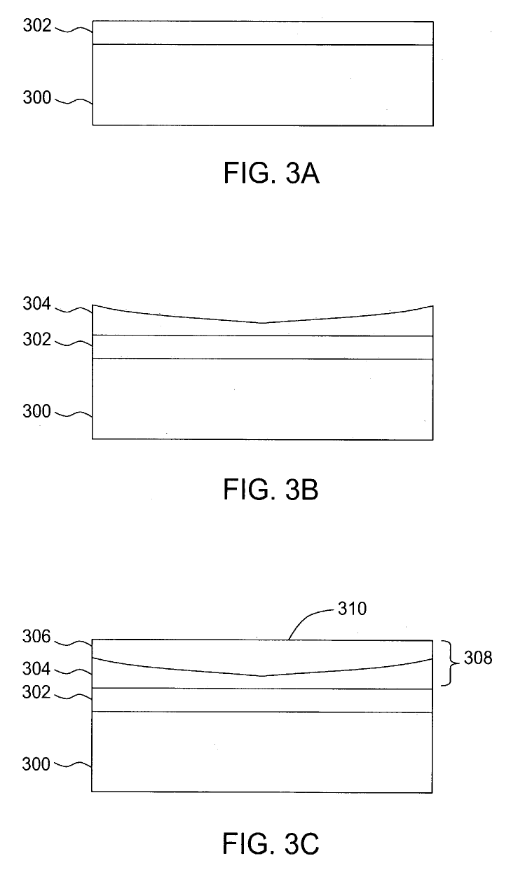

FIG. 2 depicts a flow diagram of an exemplary embodiment of the inventive method during depositing of a layer of low-k material (e.g., carbon doped silicon oxide) as a method 200. FIGS. 3A-3C together depict a sequence of schematic, cross-sectional views of a substrate having the a carbon doped silicon oxide layer being formed in accordance with the method 200 and relate to individual process steps of the method 200. For best understanding of this embodiment of the invention, the reader should refer simultaneously to FIGS. 2 and 3. The images in FIGS. 3A-3C are simplified for illustrative purposes and are not depicted to scale.

The method 200 starts at step 201 and proceeds to step 202. At step 202, a barrier layer 302 is formed on a substrate 300, such as a silicon (Si) wafer (FIG. 3A). In one embodiment, the barrier layer 302 is formed from a silicon carbide (SiC) based material. Silicon carbide processes are available from Applied Materials, Inc. of Santa Clara, Calif. under trademarks BLOK™ process or BLOK II™ process. Typically, the barrier layer 302 is deposited to a thickness of about 250 to 700 Angstroms.

The barrier layer 302 can be provided using a vacuum deposition technique such as CVD, a plasma enhanced CVD (PECVD), an evaporation, and the like. The deposition may be performed, e.g., using a respective processing reactor of a CENTURA® and ENDURA® semiconductor wafer processing systems of Applied Materials, Inc. Specifically, the CVD reactor 100 (discussed above in reference to FIG. 1) may be used to deposit the layer 302.

At step 204, the wafer 300 is placed on the support pedestal 126 in the process chamber 104 and clamped thereon. In one embodiment, the feed gas (or gas mixture) 133 is supplied to the process chamber 104 through the showerhead 120 from the gas panel 108. In this specific application of the invention the optional remote plasma source 142 (discussed in reference to FIG. 1 above) is not used, however, other equally effective applications may use the source 142. Herein the terms “gas” and “gas mixture” are used interchangeably. In one embodiment, the feed gas 133 comprises trimethysilane (SiC₃H₁₀). Alternatively, the feed gas 133 may further comprise at least one of additive gases such as oxygen (O₂) and carrier gases such argon (Ar), helium (He) and the like.

The flow rates of the gaseous elements of the feed gas 133 may individually be controlled by the showerhead 120 and/or the gas panel 108. Starting at step 204, the resistive heater 130 heats the support surface of the pedestal 126 to a temperature specified in a process recipe, while helium gas is supplied into the grooves in the support surface. As such, during step 204, the wafer 300 is heated to the temperature specified in the process recipe. In an alternative embodiment, the resistive heater 130 may pre-heat the support pedestal 126 during step 202 or prior to step 202, e.g., during processing of other wafers from a batch of the wafers.

In one illustrative embodiment, step 204 provides the feed gas 133 at a rate of about 400 to 3000 sccm, as well as oxygen at a rate of about 50 to 1000 sccm, and maintains a wafer temperature at about 250 to 400 degrees Celsius. One specific process recipe provides SiC₃H₁₀ at a rate of 1700 sccm, O₂ at a rate of 750 sccm, and a wafer temperature of 335 degrees Celsius.

At step 206, the pressure of the feed gas 133 in the process chamber 104 (also referred to as a chamber pressure) is adjusted to a predetermined level by regulating, for example, the flow rates of elements of the feed gas and the rate at which the vacuum pump evacuates the chamber. In the present invention, during step 206, the chamber pressure is set higher than during a conventional single-step CVD process in the same reactor. For example, in the illustrative embodiment discussed above, the chamber pressure of the feed gas 133, which comprises SiC₃H₁₀ and O₂, is adjusted to about 2 to 10 Torr during deposition of the dielectric layer, while one specific process recipe provides a chamber pressure of about 4 Torr. Further, in one embodiment, step 206 applies, from the RF source 121, about 200 to 1500 W of RF power at about 13.6 MHz to energize the feed gas 133 to a plasma. One exemplary process recipe applies 1100 W of RF power.

At step 208, a first phase of the deposition process (a nucleation phase) is performed at a high chamber pressure, which was set during a preceding step 206. Step 208 deposits a low-k film 304 with a concave profile (FIG. 3B). In one exemplary embodiment, the film 304 (e.g., a carbon doped silicon oxide film) is deposited during step 208 at a high chamber pressure (e.g., about 4 Torr) and has a concave profile. Such film 304 has generally a thickness non-uniformity of about 2% and thickness variations from wafer to wafer of about 3.5-4%.

At step 210, the chamber pressure of the feed gas 133 is reduced below the level used during step 208 and substantially below the level used during a conventional single-step CVD process, when such process is performed in the process chamber 104. For example, in the illustrative embodiment discussed above, the chamber pressure during step 210 is adjusted to about 1.5 to 5 Torr. One specific process recipe provides the chamber pressure of about 3 Torr.

At step 212, during a second phase of the deposition process, a film 306 is deposited on the film 304 (FIG. 3C). The film 306 integrates with the film 304 into a combined layer 308. Step 212 has a duration that continues until the combined layer 308 is formed to a predetermined thickness. In one exemplary embodiment, the film 306 (e.g., a carbon doped silicon oxide film) is deposited during step 208 at a low chamber pressure (e.g., about 3 Torr) and has a convex profile. As such, the films 304 and 306, as deposited, have inverse profiles, with the convexity of the low pressure film 306 complementing the concavity of the high pressure film 304 to form a substantially planar surface 310.

The combined layer 308 has lower thickness non-uniformity and narrower range of thickness variations than the component films 304 and 306. In the illustrative embodiment described above, during processing a batch of about 25 wafers, the thickness non-uniformity of the combined layer 308 within a wafer was between about 0.2 to 1.2%, while the thickness variations between the wafers of the batch were in a range of about 0.2 to 2%.

In this embodiment, the component films 304 and 306 were deposited at the rates of about 160 and 150 Angstroms/second, respectively. The thickness non-uniformity of the high pressure film 304 was between about 1-4%, while the low pressure film 306 had the thickness non-uniformity of about 1-4%. The time period for depositing the high pressure film 304 may be between about 10 and 90% of the time period needed to deposit the combined layer 308. A duration of the time period for depositing each of the component films 304 and 306 is selected such that the combined layer 308 has minimal thickness non-uniformity and thickness variations.

In one embodiment of the invention good results are achieved when a duration of the first phase of the deposition process (step 208) was about 15 to 30% of a total time of depositing the a carbon doped silicon oxide layer. During deposition of other low-k dielectric materials, similar results were observed when the duration of step 208 was in a range from about 10 to 90% of a total time of depositing the layer. As such, the inventive method 200 may be optimized for particular material deposition by adjusting a duration of the first phase of the deposition process, i.e., when the film 304 is deposited at high chamber pressure. The examination of the materials deposited using the invention also revealed that depositing of low-k dielectrics in accordance with the present invention does not change physical properties of the films 304 and 306, or of the combined layer 308, when compared to similar materials deposited using conventional depositing techniques.

At step 214, the method 200 stops supplying power from the RF source 121 and the heater power supply 106, as well as stops supplying the feed gas 133 and the backside gas. When pressure of the backside gas behind the wafer 300 becomes approximately equal to the gas pressure in the processing chamber 104, step 214 releases the wafer 300 from the support pedestal 126, making the wafer available for transportation out of the chamber for further processing. In an alternative embodiment, step 214 terminates power to the resistive heater 130 only after of a batch of wafers has been processed. At step 216, the method 200 ends.

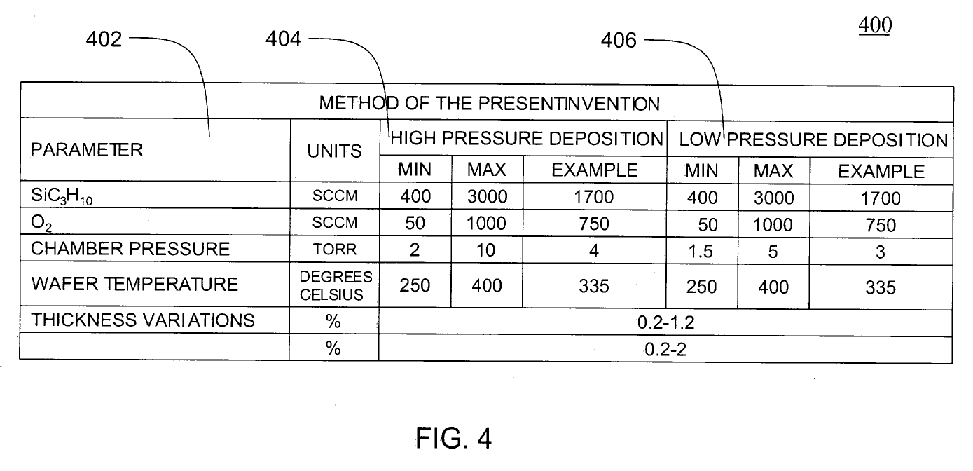

FIG. 4 presents a table 400 summarizing process parameters through which one can practice the invention using the reactor of FIG. 1. The process parameters for the embodiment of the invention presented above are summarized in column 402. The process ranges and exemplary process recipe are presented in columns 404 and 406, respectively. It should be understood, however, that the use of a different reactor may necessitate different process parameter values and ranges.

The invention can be practiced in other semiconductor processing systems wherein the processing parameters may be adjusted to achieve acceptable characteristics by those skilled in the art by utilizing the teachings disclosed herein without departing from the spirit of the invention.

While foregoing is directed to the illustrative embodiment of the present invention, other and further embodiments of the invention may be devised without departing from the basic scope thereof, and the scope thereof is determined by the claims that follow.

What is claimed is:

1. A method of depositing dielectric material upon a substrate, comprising:
providing the substrate to a deposition chamber;
maintaining a reactant gas in the deposition chamber at a first pressure during a first time period while depositing a dielectric material having a dielectric constant that is less than 4.0; and
maintaining the reactant gas in the deposition chamber at a second pressure for a second time period while depositing the dielectric material where the first pressure is higher than the second pressure.

2. The method of claim 1 wherein said dielectric material is at least one of carbon doped silicon oxide, organic doped silicon glass, and fluorine doped silicon glass.

3. The method of claim 1 wherein the dielectric material comprises carbon doped silicon oxide.

4. The method of claim 1 wherein the duration of the first time period is about 10 to 90% of the total time period for depositing the dielectric material.

5. The method of claim 1 wherein depositing of the dielectric material during the first and second time periods is performed sequentially in the same deposition chamber.

6. The method of claim 3 wherein the first pressure is about 2 to 10 Torr.

7. The method of claim 3 wherein the second pressure is about 1.5 to 5 Torr.

8. The method of claim 3 wherein depositing of the organic doped silicon glass layer further comprises:
supplying between 400 to 3000 sccm of SiC₃H₁₀;
supplying between 50 to 1000 sccm of O₂;
applying between 200 and 1500 W at about 50 kHz to 13.56 MHz;
maintaining the first pressure at about 4 Torr during first time period;
maintaining the second pressure at about 3 Torr during second time period; and
maintaining the substrate at a temperature of about 250 to 400 degrees Celsius.

9. The method of claim 1 wherein the first pressure is about 4 Torr and the second pressure is about 3 Torr.

10. The method of claim 9 wherein the first time period is 15-30% of a total time period used to deposit the dielectric material.

11. The method of claim 1 wherein a surface non-uniformity of the dielectric material is less than 1.2%.

12. A computer-readable medium containing software that, when executed by a computer, causes a reactor comprising a deposition chamber to deposit dielectric material upon a substrate using a method, comprising:
providing the substrate to a deposition chamber;
maintaining a reactant gas in the deposition chamber at a first pressure during a first time period while depositing a dielectric material having a dielectric constant that is less than 4.0; and
maintaining the reactant gas in the deposition chamber at a second pressure for a second time period while depositing the dielectric material where the first pressure is higher than the second pressure;

13. The computer-readable medium of claim 12 wherein the duration of the first time period is about 10 to 90% of a time period for depositing the dielectric material.

14. The computer-readable medium of claim 12 wherein depositing of the dielectric material during the first and second time periods is performed sequentially in the same deposition chamber.

15. The computer-readable medium of claim 12 wherein the first pressure is about 2 to 10 Torr.

16. The computer-readable medium of claim 12 wherein the second pressure is about 1.5 to 5 Torr.

17. The method of claim 12 wherein the first pressure is about 4 Torr and the second pressure is about 3 Torr.

18. The method of claim 12 wherein the first time period is 15-30% of a total time period used to deposit the dielectric material.

19. The method of claim 12 wherein a surface non-uniformity of the dielectric material is less than 1.2%.
